(19) United States
(12) Patent Application Publication
(10) Pub. No.: US 2016/0003926 A1
(43) Pub. Date: Jan. 7, 2016

(54) MEDICAL IMAGING METHOD AND APPARATUS

(71) Applicant: Siemens Aktiengesellschaft, Muenchen (DE)

(72) Inventor: Uwe Boettcher, Uttenreuth (DE)

(73) Assignee: SIEMENS AKTIENGESELLSCHAFT, Muenchen (DE)

(21) Appl. No.: 14/790,156

(22) Filed: Jul. 2, 2015

(30) Foreign Application Priority Data
Jul. 7, 2014 (DE) 102014213128.6

(51) Int. Cl. G01R 33/561; G01R 33/422; G01R 33/34

(52) U.S. Cl. CPC G01R 33/5611; G01R 33/34; G01R 33/422

(57) ABSTRACT

In a method and imaging apparatus for reconstruction of images from data recorded by the imaging device, multiple variants of a respective image are obtained with different reconstruction methods respectively applied to the acquired data.

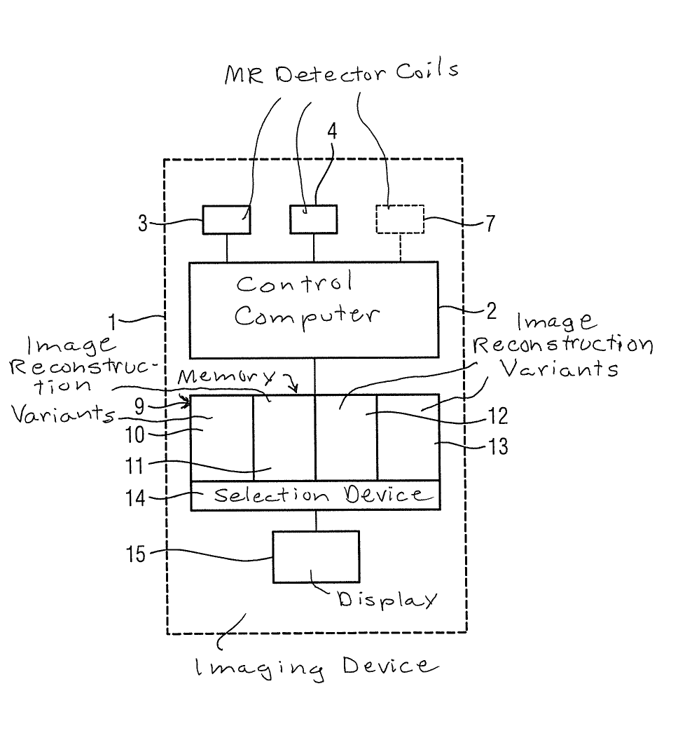

### BACKGROUND OF THE INVENTION

1. Field of the Invention

The invention relates to a method for reconstruction of images from data recorded by an imaging device. The invention further relates to a corresponding imaging device.

2. Description of the Prior Art

In methods for imaging by operating an imaging device, the actual image is obtained by the use of a wide variety of reconstruction methods from the recorded data (raw data) that are acquired. Examples of such imaging devices are an ultrasound device, an x-ray device, a computed tomography apparatus and a magnetic resonance apparatus.

The reconstruction methods differ with regard to the respective imaging device, especially in the type of mathematical transformations of the recorded data that is used, as well as in the type of the noise suppression or filtering and/or in the type of combination of different data of the same object or of a segment of the object for improving the signal-to-noise ratio (SNR), for example the type of data averaging, etc. The quality of the image is different in each case for the different reconstruction methods with respect to the object to be examined. For example, an image obtained for the same object using one specific reconstruction method can show an undesired artifact, and an image obtained using another reconstruction method can appear without an artifact.

In particular, as a result of the large amounts of data recorded, in current devices that apply a method of image reconstruction to the recorded data that are acquired, the reconstruction method is selected at the time of image recording, or a reconstruction method is preset by default. For storage space reasons, the raw data are retained only for a specific period of time after the reconstruction, and are then deleted. A disadvantageous under some circumstances is that it is not known, at the time that the image is recorded, which reconstruction method would deliver the best image quality in each case.

### SUMMARY OF THE INVENTION

An object of the invention is to provide a method of the type described above for imaging that offers a simple option of displaying the image with the most suitable reconstruction method in each case.

This object is achieved in accordance with the invention by a method for reconstruction of images from data recorded by an imaging device, wherein a number of variants of a respective image are obtained with different reconstruction methods in each case.

The invention thus allows, in a simple manner, several variants of the respective image to be created with different reconstruction methods from the recorded data acquired. After creation of the different image variants the recorded raw data no longer have to be retained. From among the variants created in each case, the variant can be selected, especially at a later time, which contains the desired best image quality for the viewer.

The inventive method thus offers a surprisingly simple option for delivering to a viewer or a user, at a later point in time in relation to the image recording, a reconstructed image that has the quality desired by that viewer or user, even though the most suitable reconstruction method for the image is not known at the point of image recording. The method operates in a resource-saving manner, since a large amount of raw data does not have to be stored and retained.

Advantageously the number of variants of the image is obtained in parallel and especially directly after or during the image acquisition.

Expediently the number of variants of the image files is stored so that, at any given later point in time, the image files can be selected for a viewer with respect to the desired image quality. In such cases the method offers the additional advantage that image variants can be retained for selection that are useful in each case for different requirements of the viewer. For example, an image variant can be useful for viewing a specific spatial subarea or can have the best quality for this purpose, whereas another image variant can be useful for obtaining information under another aspect.

In a preferred embodiment, data recorded by a medical imaging device are employed for the reconstruction. In such cases the specified method, because of the large amounts of data to be processed, is especially suitable for multiple reconstruction of the recorded data of an ultrasound device, an x-ray device, a computed tomography device and/or a magnetic resonance device.

In modern methods for imaging by magnetic resonance (MR), sets of magnetic resonance data are obtained in parallel using multiple, separate detector coils. The respective image of the object being examined is reconstructed with spatial resolution from the multiple magnetic resonance data sets obtained in parallel. The recording of data with a number of detector coils leads to a higher signal-to-noise ratio in the data, especially in the vicinity of the individual coil elements. In addition this type of data recording offers the option of accelerating the measurement and can thus shorten the examination time for the patient to be examined.

Reception coils, composed of a number of detector coils, are usually referred to as phased array coils.

Because of differing coil sensitivities of the different detector coils or through crosstalk between RF fields, undesired artifacts can result in the image reconstructed from the magnetic resonance data of a number of coils, or a relatively low signal-to-noise ratio (SNR). For this reason various reconstruction methods are known in the literature that improve the quality of an MR image obtained with a number of detector coils, and in particular increase the SNR. For example the method of sensitivity encoding (SENSE), the method of simultaneous acquisition of spatial harmonics (SMASH), the method of coherent addition, the method of image-based sensitivity estimation, the method of adaptive filtering and the method of summing of squares (SoS) are known, for which the reader is referred to E. G. Larsson et al, SNR-optimality of sum-of-squares reconstruction for phased-array magnetic resonance imaging, Journal of Magnetic Resonance 163 (2003), P. 121-123 and to D. O. Walsh et al, Adaptive reconstruction of phased array MR imagery, Magnetic Resonance in Medicine 43 (2000), P. 682-690.

In the SENSE (sensitivity encoding) method, during the reconstruction, use is made of the fact of data encoding of the individual detector coils on the basis of their different sensitivities in each case. In the SMASH (Simultaneous Acquisition of Spatial Harmonics) method linear combinations of sensitivity functions to approximate to harmonics in the observed field of view are used (see also: K. P. Pruessmann et al, SENSE: Sensitivity Encoding for Fast MRI, Magnetic Resonance in Medicine 42 (1999), S. 952-962). In the method of coherent addition, after phase compensation the data of different detector coils is overlaid coherently. In the method of image-based sensitivity estimation an estimation of the sensitivities of the individual coil is undertaken with reference to the data acquired. In adaptive filtering an adaptive filter for noise suppression specifically designed for the respective arrangement of detector coils is employed. With the SoS method quadratic mean values are formed from the number of items of magnetic resonance data, by which small signals are suppressed.

Advantageously therefore a number of magnetic resonance data sets are recorded by multiple detector coils in a magnetic resonance device, wherein in each case a number of features of the magnetic resonance data are employed for reconstruction of an image.

Preferably in such cases the different reconstruction methods are selected from a group that includes sensitivity encoding (SENSE), acquisition of spatial harmonics (SMASH), coherent addition, image-based sensitivity estimation, adaptive filtering, and summing of squares (SoS). An appropriate selection is made with respect to the differing nature of the selection methods with respect to artifacts, and with respect to the SNR.

The inhomogeneous reception profile of the individual reception coils results in marked differences in signals in the individual detector coils. The signal differences can be counteracted with appropriate RF filters. However, when it is used, the strength of the respective RF filter is not known under some circumstances. In this respect, in a further embodiment, the different reconstruction methods are carried out with different RF filters on the detector side. In this context, “different reconstruction methods” means reconstruction methods that, although they are designed with the same mathematical algorithm, are nevertheless designed with different RF filters. Moreover, even for different mathematical algorithms or reconstruction methods, each of these variants can also be carried out with different RF filters.

The invention also further relates to an imaging device with a control device which is configured and embodied to implement the method described above. The advantages of the method and its embodiment variants are applied analogously to the imaging device.

Preferably the imaging device includes a memory that is configured and embodied for storing the number of variants of the image.

Expediently the imaging device includes a selection device configured and embodied for selection of one of the number of variants of the image by a user. The selection device can include a display unit, for example, which graphically displays to the user the respective variants of the image for selection.

Preferably the imaging device is embodied as a magnetic resonance device with multiple detector coils.

### BRIEF DESCRIPTION OF THE DRAWING

The single FIGURE schematically illustrates an imaging device constructed and operating in accordance with the present invention.

### DESCRIPTION OF THE PREFERRED EMBODIMENTS

The exemplary embodiment of the invention schematically shown in the single drawing includes an imaging device 1 embodied as a magnetic resonance apparatus with a control computer 2, and with multiple detector coils 3, 4, 7, which are configured for parallel acquisition of respective magnetic resonance data. The control computer 2 is configured to reconstruct an MR image for a field of view of interest in each case from the different magnetic resonance data set of the number of detector coils 3, 4, 7. The detector coils 3, 4, 7 are embodied as a so-called phased array.

The control computer 2 is additionally configured and embodied to create, from the different magnetic resonance data sets of the various detector coils, a number of variants of the MR image, wherein for each of these variants a different reconstruction method is applied. The different variants of the MR image are stored in a memory 9 after creation. In the shown exemplary embodiment, a first variant 10, a second variant 11, a third variant 12 and a fourth variant 13 of the MR image are created. The variants 10 to 13 of the MR image are respectively created, for example, according to the method of adaptive filtering, according to the method of summing of squares, according to the method of coherent addition or according to the method of sensitivity encoding. As an alternative, different RF filters can also be used for the different variants 10 to 13 of the MR image, which take into account the RF effects at the different detector coils 3, 4, 7. If required, a user is presented graphically with the different image variants at a display device 15 for selection among them via a selection device 14 (user interface). Depending on what the user wants, the respective best variant of the MR image with respect to image quality can then be included for viewing.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for reconstruction of images from acquired data, said method comprising:
operating an imaging apparatus to acquire image data from a subject with which the imaging apparatus interacts;
providing the acquired data to a processor and, in said processor, reconstructing a plurality of different images of the subject by applying a plurality of different reconstruction algorithm variants respectively to the acquired data; and
making the respective images each available from the processor in electronic form as a data file.

2. A method as claimed in claim 1 comprising reconstructing said respective images in said processor in parallel.

3. A method as claimed in claim 1 comprising providing each of said data files to a memory and storing the respective data files of the respective different images in said memory.

4. A method as claimed in claim 1 comprising employing a medical imaging apparatus as said imaging apparatus, and acquiring medical imaging data from the subject as said acquired data, and reconstructing respective three different medical images of the subject, as said respectively different images.

5. A method as claimed in claim 4 comprising selecting said medical imaging apparatus from the group consisting of ultrasound apparatuses, x-ray apparatuses, computed tomography apparatuses, and magnetic resonance apparatuses.

6. A method as claimed in claim 1 comprising employing a magnetic resonance apparatus comprising a plurality of detector coils that acquire magnetic resonance data, as said imaging apparatus, and using magnetic resonance features of said magnetic resonance data for reconstruction of respective magnetic resonance images of the subject.

7. A method as claimed in claim 6 comprising selecting said respectively different reconstruction algorithms for said magnetic resonance data from the group consisting of sensitivity encoding (SENSE) methods, spatial harmonics acquisition (SMASH), coherent addition, image-based sensitivity estimation, adaptive filtering, and summing of squares.

8. A method as claimed in claim 6 comprising reconstructing the respectively different magnetic resonance images using respectively different reconstruction algorithms with respectively different radio-frequency (RF) filters applied to respective sets of magnetic resonance data acquired with the respective detector coils.

9. An imaging apparatus for reconstruction of images from acquired data, comprising:
an imaging device;
a control computer configured to operate the imaging device to acquire image data from a subject with which the imaging apparatus interacts;
a processor provided with, the acquired data, said processor being configured to reconstruct a plurality of different images of the subject by applying a plurality of respectively different reconstruction algorithm variants respectively to the acquired data; and
said processor being configured to make the respective images each available from the processor in electronic form as a data file.

10. An imaging apparatus as claimed in claim 9 wherein said processor is configured to reconstruct said respective images in parallel.

11. An imaging apparatus as claimed in claim 9 comprising a memory, and wherein said processor is configured to provide each of said data files to said memory and store the respective data files of the respective different images in said memory.

12. An imaging apparatus as claimed in claim 9 wherein said medical device is a medical imaging device, and wherein said control computer is configured to operate said medical imaging device to acquire medical imaging data from the subject as said acquired data, and wherein said processor is configured to reconstruct respective three different medical images of the subject, as said respectively different images.

13. An imaging apparatus as claimed in claim 12 wherein said medical imaging device is selected from the group consisting of ultrasound devices, x-ray devices, computed tomography devices, and magnetic resonance devices.

14. An imaging apparatus as claimed in claim 9 wherein said imaging device is a magnetic resonance device comprising a plurality of detector coils that acquire magnetic resonance data, and wherein said processor is configured to use magnetic resonance features of said magnetic resonance data for reconstruction of respective magnetic resonance images of the subject.

15. An imaging apparatus as claimed in claim 14 wherein said processor is configured to use different reconstruction algorithms for said magnetic resonance data selected from the group consisting of sensitivity encoding (SENSE) methods, spatial harmonics acquisition (SMASH), coherent addition, image-based sensitivity estimation, adaptive filtering, and summing of squares.

16. An imaging apparatus as claimed in claim 14 wherein said processor is configured to reconstruct the respectively different magnetic resonance images using respectively different reconstruction algorithms with different radio-frequency (RF) filters respectively applied to respective sets of magnetic resonance data acquired with the respective detector coils.
